(19) United States
(12) Patent Application Publication
(10) Pub. No.: US 2019/0273215 A1
(43) Pub. Date: Sep. 5, 2019

(54) QUANTUM DOT LIGHT-EMITTING DIODE DEVICES AND MANUFACTURING METHODS, APPARATUSES THEREOF

(71) Applicants: Kunshan New Flat Panel Display Technology Center Co., Ltd., Kunshan (CN); KunShan Go-Visionox Opto-Electronics Co., Ltd., Jiangsu (CN)

(72) Inventors: Jiantai WANG, Kunshan (CN); Rubo XING, Kunshan (CN); Xiaolong YANG, Kunshan (CN); Huimin LIU, Kunshan (CN); Ping SUN, Kunshan (CN); DONG WEI, Kunshan (CN)

(73) Assignees: Kunshan New Flat Panel Display Technology Center Co., Ltd., Kunshan (CN); KunShan Go-Visionox Opto-Electronics Co., Ltd., Jiangsu (CN)

(21) Appl. No.: 16/419,376

(22) Filed: May 22, 2019

Related U.S. Application Data
(63) Continuation of application No. PCT/CN2018/088755, filed on May 28, 2018.

(30) Foreign Application Priority Data
Jan. 31, 2018 (CN) 201810098253.5

(51) Int. Cl. H01L 51/50; H01L 51/56; H01L 51/00

(52) U.S. Cl. CPC H01L 51/502; H01L 51/5072; H01L 51/5056; H01L 51/50; H01L 51/0007; H01L 51/0039; H01L 51/0035; H01L 2251/5369; H01L 51/56

(57) ABSTRACT

The disclosure relates to the field of light-emitting device technology, and in particular to a quantum dot light-emitting diode device and a manufacturing method, an apparatus thereof. The device includes: a quantum dot light-emitting layer, a first transport layer located over the quantum dot light-emitting layer, a first barrier layer located between the quantum dot light-emitting layer and the first transport layer, the first barrier layer containing a polymer electrolyte, which is configured to block at least a portion of the nanoparticles in the first transport layer from leaking into the quantum dot light-emitting layer.

### CROSS REFERENCE

This application is a continuation of International Application No. PCT/CN2018/088755, filed on May 28, 2018, which claims priority to Chinese Patent Application No. 201810098253.5, entitled “QUANTUM DOT LIGHT-EMITTING DIODE DEVICES AND MANUFACTURING METHODS, APPARATUSES THEREOF” filed on Jan. 31, 2018, the contents of which are expressly incorporated by reference herein in their entireties.

### FIELD OF THE DISCLOSURE

Exemplary embodiments of the disclosure relate to the field of display technology, and in particular to quantum dot light-emitting diode devices and manufacturing methods, apparatuses thereof.

### BACKGROUND

Quantum Dot Light-Emitting Diodes (QLEDs) are new type of self-luminous technology that requires no additional light source. Quantum Dots are invisible to the naked eye and extremely small semiconductor nanocrystals, and the particle diameter ranges between a few nanometers and tens of nanometers.

As shown in FIG. 1, FIG. 1 is a schematic structural diagram of film layers in an existing QLED device. The film layers of the device sequentially mainly includes from top to bottom a cathode 01, an electron transport layer 02, a quantum dot light-emitting layer 03, a hole transport layer 04, an anode 05 and the like. Further, an electron injection layer, a hole injection layer and the like may also be included, which are not shown in FIG. 1.

### SUMMARY

Exemplary embodiments of the disclosure provide quantum dot light-emitting diode devices and manufacturing methods, apparatuses thereof for alleviating the problem of the influence on the performance of a quantum dot light-emitting layer caused by a leakage of nanoparticles in a first transport layer formed on the quantum dot light-emitting layer in the prior art.

Exemplary embodiments of the disclosure adopt the following technical schemes:

a quantum dot light-emitting diode device, comprising: a quantum dot light-emitting layer, a first transport layer located above the quantum dot light-emitting layer, and a first barrier layer located between the quantum dot light-emitting layer and the first transport layer, the first barrier layer comprising a polymer electrolyte;

the first barrier layer blocking at least a portion of nanoparticles in the first transport layer from leaking to the quantum dot light-emitting layer.

Preferably, the device further comprises: a second transport layer located below the quantum dot light-emitting layer;

a second barrier layer located between the second transport layer and the quantum dot light-emitting layer, the second barrier layer comprising a polymer electrolyte.

Preferably, in the device, the polymer electrolyte has a net-shaped structure.

Preferably, in the device, the net-shaped structure is made of a chain polymer electrolyte.

Preferably, in the device, wherein the barrier layer has a thickness of 8 to 15 nm.

Preferably, in the device, the polymer electrolyte comprises any one or more of amine-containing polyfluorenes conjugated polymers PFN, phenolic resins PF, renewable polyethylene terephthalate PETE, polyetherimide PEI, polyterephthalate plastics PET and polyethylene naphthalate.

A method of manufacturing a quantum dot light-emitting diode device, comprising:

forming a quantum dot light-emitting layer; forming a first barrier layer over the quantum dot light-emitting layer, the first barrier layer comprising a polymer electrolyte; forming a first transport layer over the first barrier layer;

the first barrier layer blocking at least a portion of nanoparticles in the first transport layer from leaking to the quantum dot light-emitting layer.

Preferably, in the method, the forming a first barrier layer over the quantum dot light-emitting layer specifically comprises:

dissolving a polymer electrolyte with a first solvent to form a first solution having a preset concentration;

depositing the first solution over the quantum dot light-emitting layer to form the first barrier layer.

Preferably, in the method, a second solvent used to dissolve the nanoparticles when forming the first transport layer is immiscible with the first solvent.

Preferably, the first solvent is a polar solvent and the second solvent is a non-polar solvent.

Preferably, in any one of the methods of manufacturing a quantum dot light-emitting diode device, before forming the quantum dot light-emitting layer, the method further comprises:

forming a second transport layer; forming a second barrier layer over the second transport layer, the second barrier layer comprising a polymer electrolyte.

Preferably, in the above method, the forming a second barrier layer over the second transport layer specifically comprises:

dissolving a polymer electrolyte with a third solvent to form a third solution having a preset concentration;

depositing the third solution on the second transport layer to form the second barrier layer.

Preferably, in the method, the preset concentration is less than 1 mg/ml.

A quantum dot light-emitting diode apparatus comprises any one of the above quantum dot light-emitting diode devices.

The following beneficial effects can be achieved by at least one technical solution adopted by the disclosure:

By an above technical scheme of exemplary embodiments of the disclosure, the first barrier layer is formed on the quantum dot light-emitting layer of the quantum dot light-emitting diode device, the first transport layer is formed on the first barrier layer, the barrier layer contains a plurality of chain polymer electrolytes which form a dense net-shaped structure, and blocks nanoparticles in the above transport layer, and avoids the nanoparticles from leading into the quantum dot light-emitting layer by gravity, thereby ensuring the light-emitting performance of the quantum dot light-emitting layer. In addition, since the end group carried by the polymer electrolyte can modify the surface defects of the nanoparticles at the contact interface between the quantum dot light-emitting layer and the adjacent transport layer, and modify the nanoparticles in contact with each other, thereby improving the interface, and therefore, the barrier layer can improve the performance of the quantum dot light-emitting device.

### BRIEF DESCRIPTION OF THE DRAWINGS

The drawings described herein are provided for further understanding the disclosure and as a part of the disclosure. The exemplary embodiments of the disclosure and description thereof are used to explain exemplary embodiments of the disclosure and not as any improper limitation to the disclosure. In the drawings:

FIG. 1 is a schematic structural diagram of film layers of a quantum dot light-emitting diode in the prior art;

FIG. 2 is a first flowchart of a method for manufacturing a QLED device provided by an exemplary embodiment of the disclosure;

FIG. 3 is a second flowchart of a method for manufacturing a QLED device provided by an exemplary embodiment of the disclosure;

FIG. 4 is a third flowchart of a method for manufacturing a QLED device provided by an exemplary embodiment of the disclosure;

FIG. 5 is a flowchart of a method for forming a second barrier layer on a second transport layer in an exemplary embodiment of the disclosure;

FIG. 6 is a first schematic structural diagram of film layers of a QLED device provided by an exemplary embodiment of the disclosure;

FIG. 7a is a second schematic structural diagram of film layers of a QLED device provided by an exemplary embodiment of the disclosure;

FIG. 7b is a third schematic structural diagram of film layers of a QLED device provided by an exemplary embodiment of the disclosure;

FIG. 8 is a fourth schematic structural diagram of film layers of a QLED device provided by an exemplary embodiment of the disclosure;

FIG. 9a is a fifth schematic structural diagram of film layers of a QLED device provided by an exemplary embodiment of the disclosure;

FIG. 9b is a sixth schematic structural diagram of film layers of a QLED device provided by an exemplary embodiment of the disclosure.

### DETAILED DESCRIPTION OF PREFERRED EXEMPLARY EMBODIMENTS

Since a transition metal oxide (such as zinc oxide, titanium oxide) has excellent visible light transmittance and work function adjustability, the transition metal oxide is a preferred material for the electron transport layer in the QLED device. However, since the electron transport layer and the quantum dot light-emitting layer are generally composed of inorganic materials having semiconductor properties, and the electron transport layer and the quantum dot light-emitting layer are often in direct contact, so that during the preparation of the transition metal oxide electron transport layer on the quantum dot light-emitting layer in the prior art, there is a leakage of the nanoparticles in the upper layer into the lower layer or even mutual solubility between the layers, thereby generating defects in the quantum dot light-emitting layer and further affecting the performance of the QLED device.

In order to make the purposes, technical solutions and advantages of the disclosure clearer, the technical solutions of the disclosure will be clearly and completely described below in conjunction with the specific exemplary embodiments and the corresponding drawings. It is apparent that the described exemplary embodiments are merely part of the exemplary embodiments of the disclosure rather than all the exemplary embodiments. Based on the exemplary embodiments in the disclosure, all the other exemplary embodiments obtained by a person skilled in the art without paying creative work will fall into the protection scope of the disclosure.

The technical solutions provided by exemplary embodiments of the disclosure will be described in detail below in conjunction with the drawings. The schematic structural diagram of the film layers provided by the disclosure only shows the positional relationship among different film layers, and does not represent the actual thickness of the film layers.

### Exemplary Embodiment 1

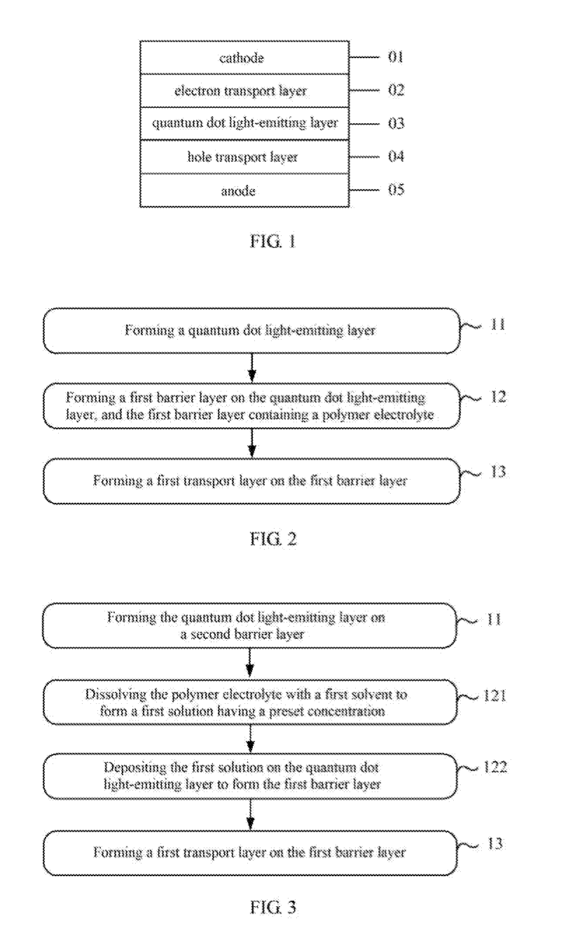

The exemplary embodiment of the disclosure provides a method for manufacturing a QLED device. As shown in FIG. 2, the method mainly includes the following steps:

Step 11: forming a quantum dot light-emitting layer.

In a specific manufacturing process, the quantum dot light-emitting layer can be prepared by a solution method. The quantum dot light-emitting layer can be fabricated on a substrate. Before fabricating the quantum dot light-emitting layer, the method may further include the steps of sequentially fabricating an anode, a hole transport layer and the like on the substrate.

Step 12: forming a first barrier layer on the quantum dot light-emitting layer, and the first barrier layer containing a polymer electrolyte.

Wherein the first barrier layer is configured to block at least a portion of the nanoparticles in a first transport layer from leaking to the quantum dot light-emitting layer. The polymer electrolyte is an electrolyte material in the form of a polymer, often a polymer having a dipole, and specifically an ionically conductive polymer or an ion exchange membrane. The polymer electrolyte may be materials such as amine-containing polyfluorenes conjugated polymers PFN, phenolic resins PF, renewable polyethylene terephthalate PETE, polyetherimide PEI, polyterephthalate plastics PET and polyethylene naphthalate PEN. The first barrier layer formed on the quantum dot light-emitting layer has a net-shaped structure. The polymer electrolyte is generally chain-like, and a plurality of chain polymer molecules having different lengths and different forms are entangled together to form the first barrier layer having a relatively dense net-shaped structure.

In addition, it should be noted that the above first barrier layer may include not only the above polymer electrolyte, but also other organic or inorganic materials capable of forming a similar barrier structure or contributing to the formation of a dense net-shaped structure, so as to strengthen the compact degree or blocking capacity of the first barrier layer.

Step 13: forming a first transport layer on the first barrier layer.

Specifically, the first transport layer having a certain thickness may be deposited on the formed first barrier layer by a deposition process, and the material of the first transport layer includes inorganic nanoparticles having semiconductor properties. Firstly, the above nanoparticles are dissolved to form a nanoparticle solution, and then a film layer of the nanoparticle solution is formed on the first barrier layer by deposition manners such as coating or printing, and a solvent in the solution is finally removed by a manner of heating/vacuum evaporation and the nanoparticles are left on the first barrier layer to form the first transport layer. Preferably, the above nanoparticles may be transition metal oxide materials such as zinc oxide and titanium oxide.

In the QLED device formed by the above steps, the first barrier layer serves to block the nanoparticles in the first transport layer from leaking to the quantum dot light-emitting layer. And the first barrier layer is located on the quantum dot light-emitting layer, and the first transport layer is located on the first barrier layer, thereby forming the structure in which the first barrier layer is sandwiched between the quantum dot light-emitting layer and the first transport layer. The first barrier layer is composed of a plurality of chain polymer electrolytes, has a dense net-shaped structure, effectively separates the first transport layer from the quantum dot light-emitting layer, can block most of the nanoparticles and alleviate the leakage of the nanoparticles by gravity into the quantum dot light-emitting layer, and even block all the nanoparticles, thereby avoiding the nanoparticle from falling into the quantum dot light-emitting layer due to gravity. Therefore, the first barrier layer can alleviate the problem of the influence on the performance of the quantum dot light-emitting layer caused by the leakage of the nanoparticles in the first transport layer formed on the quantum dot light-emitting layer in the prior art.

In fact, it should be noted that the first transport layer involved in the disclosure may be an electron transport layer or a hole transport layer, as long as the first transport layer fabricated on the film layer of the quantum dot light-emitting layer is satisfied. Thus, there is a problem of leakage of the nanoparticles in the first transport layer located in the upper layer into the quantum dot light-emitting layer due to gravity. In the disclosure, the first barrier layer is fabricated between the quantum dot light-emitting layer and the first transport layer, and a net-shaped structure having a certain compact degrees is formed by the polymer electrolyte contained in the first barrier layer, thereby blocking the nanoparticles in the first transport layer from leaking into the quantum dot light-emitting layer and avoiding mutual solubility of film layers between the first transport layer and the quantum dot light-emitting layer during the fabrication process.

### Exemplary Embodiment 2

Based on the above scheme, a method for manufacturing the QLED device provided by an exemplary embodiment of the disclosure is shown in FIG. 3, and specifically comprises:

Step 11: Forming a quantum dot light-emitting layer.

Specifically, steps of the method for forming the quantum dot light-emitting layer may be shown in the above exemplary embodiment, which are not described in detail herein again. The process of forming the first barrier layer in step 12 can be specifically implemented by the following steps 121 and 122.

Step 121: Dissolving the polymer electrolyte with a first solvent to form a first solution having a preset concentration.

In this step, a first solvent for dissolving the polymer electrolyte is determined; given that it is necessary to fabricate the first barrier layer on the quantum dot light-emitting layer, in order to avoid mutual solubility of solvents between adjacent film layers, when fabricating the adjacent film layers, it is necessary to perform dissolution processing by selecting and using solvents which are mutually orthogonal (i.e., mutual insolubility) for dissolving solute (various types of nanoparticles). Since the solvent for dissolving the nanoparticles in the quantum dot emitting layer is generally a non-polar solvent, a polar solvent is required to dissolve the polymer electrolyte.

Preferably, a polar solvent-alcohol solution is selected, which has good solubility for the polymer electrolyte, and the alcohol solution and the non-polar solvent are orthogonal solvents, thereby avoiding the phenomenon of mutual solubility with the quantum dot film layer.

Step 122: depositing the first solution on the quantum dot light-emitting layer to form the first barrier layer.

Wherein the first barrier layer is configured to block at least a portion of the nanoparticles in the first transport layer from leaking to the quantum dot light-emitting layer. In this step, the deposition process specifically includes process manners such as coating, dip coating, spraying, printing and spin coating, and the solution is uniformly deposited on the quantum dot light-emitting layer by the above deposition process, and finally the solvent can be evaporated by heating/vacuum method to form the desired film layer, and such process is relatively simple and quality of the film-forming is relatively high.

Optionally, in the disclosure, considering that the conductivity of the polymer electrolyte is often inferior to that of the nanoparticles, in order to ensure the conductivity of the above transport layer, the above preset concentration should be less than 1 mg/ml. When the first barrier layer is too thick, it will hinder electron conduction, reduce the conductivity and have a certain insulating effect, thereby affecting the overall performance of the QLED device; when the first barrier layer is too thin, the net-shaped structure is insufficiently dense and unable to effectively block the nanoparticles from leaking into the quantum transport layer. Therefore, in order to ensure that the chain polymer electrolyte can form a net-shaped structure with a certain compact degrees, it is necessary to control the thickness of the first barrier layer to make it greater than or equal to 8 nanometers and less than or equal to 15 nanometers when fabricating, so that the first barrier layer with a barrier function is formed, and at the same time, the formed first barrier layer having good electrical conductivity is ensured, thereby reducing the barrier to electron transport.

Meanwhile, the method further includes step 13: forming the first transport layer on the first barrier layer. The specific steps are as described in the foregoing exemplary embodiment, which are not described herein again.

The exemplary embodiment of the disclosure shows a specific implementation of the foregoing step 12. Of course, it should be understood that the step 12 can also be implemented in other manners, which is not limited by the exemplary embodiments of the disclosure.

Optionally, when forming the first barrier layer, the first solvent used is immiscible with the solvent used to fabricate the quantum dot light-emitting layer, and further, in order to avoid mutual solubility of solvents between the first barrier layer and the first transport layer located thereon, the second solvent used to dissolve the nanoparticles when forming the first transport layer may be defined to be immiscible with the first solvent.

The QLED device formed by the above steps can form the first barrier layer between the first transport layer and the quantum dot light-emitting layer, and the first barrier layer is composed of a plurality of chain polymer electrolytes having a dense net-shaped structure. The first barrier layer serves to block the nanoparticles in the first transport layer from leaking to the quantum dot light-emitting layer during deposition of the first transport layer. In addition, since the polymer electrolyte is an electrolyte material in the form of a polymer, at least a portion of the polyelectrolyte has an end group extending outwardly from the surface of the layer, and the end group thereof can improve surface defects of the nanoparticles in the first transport layer, the second transport layer and the quantum dot light-emitting layer in contact therewith to some extent, thereby improving the properties of the interface contact and performing the function of modifying the interface.

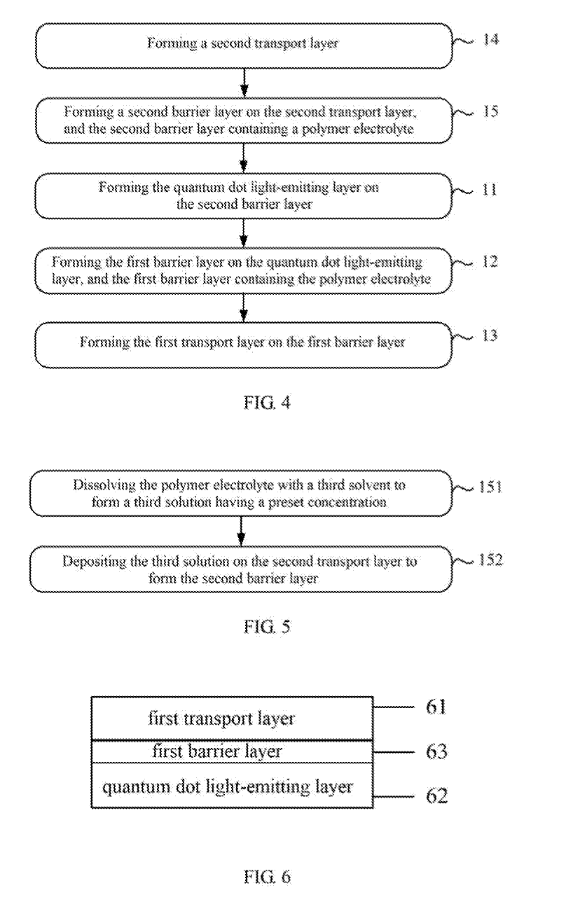

Based on the above scheme, it should be noted that, as indicated in the background art, the leakage of nanoparticles is occurred only for inorganic nanoparticles. And, considering that the nanoparticles in the quantum dot light-emitting layer, they may also leak into the underlying transport layer and affect the properties of the film layers. With reference to FIG. 4, before forming the quantum dot light-emitting layer, the method further includes:

Step 14: forming a second transport layer.

Specifically, the second transport layer may be composed of inorganic nanoparticles having semiconductor properties, and may be prepared by a solution method using materials such as zinc oxide or titanium oxide. Specifically, the nanoparticles are first dissolved to form a nanoparticle solution, and a nanoparticle solution layer is then formed on the substrate by deposition methods such as coating or printing. Finally, the solvent in the solution can be removed by heating/vacuum evaporation, and the nanoparticles are retained to form a second transport layer. Wherein, the substrate may be provided with a cathode or an anode, or a hole transport layer or an electron transport layer, and the thickness of the second transport layer prepared in this step may be less than 100 nm.

Step 15: forming a second barrier layer on the second transport layer, and the second barrier layer containing the polymer electrolyte.

The second barrier layer is configured to block the nanoparticles in the quantum dot light-emitting layer from leaking to the second transport layer.

Optionally, as shown in FIG. 5, step 15 may specifically include:

Step 151: dissolving the polymer electrolyte with a third solvent to form a third solution having a preset concentration.

The third solvent may be the same as or different from the first solvent, and preferably, the third solvent is a polar solvent for subsequently dissolving the nanoparticles in the quantum dot light-emitting layer with the non-polar solvent, and when further preparing the quantum dot light-emitting layer on the second barrier layer, mutual solubility of solvents between the third solvent and the solvent used to dissolve the nanoparticles in quantum dot light-emitting layer is avoided, and leakage or mutual solubility of layers between the subsequently prepared quantum dot light-emitting layer and the second barrier layer is reduced.

Step 152: depositing the third solution on the second transport layer to form the second barrier layer.

The second barrier layer is configured to block at least a portion of the nanoparticles in the quantum dot light-emitting layer from leaking to the second transport layer. Preferably, the preset concentration is less than 1 mg/ml and can be specifically prepared by a solution method. Steps of the specific solution method are as described above, which will not be described here again. The second barrier layer formed by the above method serves to separate the second transport layer from the quantum dot light-emitting layer, and at the same time, ensures that the second barrier layer has good electrical conductivity and reduces the barrier to electron conduction.

The above scheme can deposit the dissolved chain polymer electrolyte on the second transport layer, and at the same time, since the solvent used to prepare the second transport layer is immiscible with the solvent used to prepare the quantum dot light-emitting layer, the mutual solubility phenomenon between the second transport layer and the subsequently formed quantum dot light-emitting layers is avoided, thereby ensuring the performance of the prepared quantum dot light-emitting layer.

In addition, the concentration of the polymer electrolyte in the third solution may be the same as or different from the concentration of the polymer electrolyte in the first solution, and the polymer electrolyte in the third solution may be the same as or different from the polymer electrolyte in the first solution.

It should be noted that the serial numbers for the steps in the disclosure do not represent the order of the steps, but based on the explanation of the specification and the drawings in the specification.

The QLED device formed by the above steps can form the first barrier layer between the first transport layer and the quantum dot light-emitting layer. The first barrier layer is composed of a plurality of chain polymer electrolytes having a dense net-shaped structure. The first barrier layer serves to block the nanoparticles in the first transport layer from leaking to the quantum dot light-emitting layer during the deposition of the first transport layer. Similarly, the second barrier layer is fabricated on the formed second transport layer, and the second barrier layer is composed of a plurality of chain polymer electrolytes having a dense net-shaped structure. during the process of manufacturing the quantum dot light-emitting layer on the second barrier layer, the net-shaped second barrier layer can prevent the nanoparticles in the quantum dot light-emitting layer from leaking into the second transport layer by gravity, thereby ensuring the performance of the quantum dot light-emitting layer. In addition, since the polymer electrolyte is an electrolyte material in the form of a polymer, the end group thereof can improve surface defects of the nanoparticles in the first transport layer, the second transport layer and the quantum dot light-emitting layer in contact therewith to some extent, thereby improving the properties of the interface contact and performing the function of modifying the interface.

### Exemplary Embodiment 3

The film layer structure of the QLED device provided by the exemplary embodiment of the disclosure is shown in FIG. 6, and mainly includes: a quantum dot light-emitting layer 62, a first transport layer 61 located above the quantum dot light-emitting layer 62, and a first barrier layer 63 located between the quantum dot light-emitting layer 62 and the first transport layer 61, and the first barrier layer 63 containing a polymer electrolyte. The first barrier layer 63 is configured to block at least a portion of the nanoparticles in the first transport layer 61 from leaking into the quantum dot light-emitting layer 62.

Given that in the disclosure, the first transport layer may be an electron transport layer or a hole transport layer, when the first barrier layer is only present, the QLED device may comprise the following two structures:

Structure 1: the first transport layer is the electron transport layer.

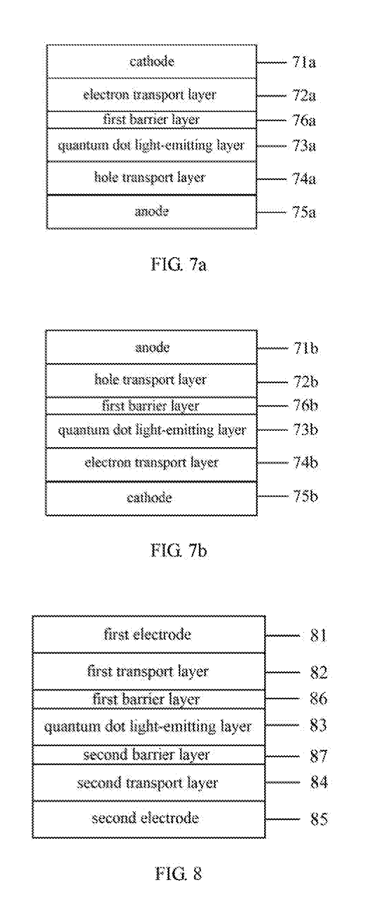

As shown in FIG. 7a, the QLED device may include a cathode 71a, an electron transport layer 72a, a quantum dot light-emitting layer 73a, a hole transport layer 74a, an anode 75a, and a first barrier layer 76a located between the electron transport layer 72a and the quantum dot light-emitting layer 73a.

For the QLED device described above, the first barrier layer 76a located between the quantum dot light-emitting layer 73a and the electron transport layer 72a is composed of a plurality of chain polymer electrolytes, and a net-shaped structure having a certain compact degrees is formed by the polymer electrolyte contained in the first barrier layer 76a, and the net-shaped structure can block the nanoparticles in the electron transport layer 72a and alleviate the penetration of the nanoparticles into the quantum dot light-emitting layer 73a by gravity, thereby ensuring the light-emitting performance of the quantum dot light-emitting layer 73a.

Structure 2: the first transport layer is the hole transport layer.

As shown in FIG. 7b, the QLED device may include an anode 71b, a hole transport layer 72b, a quantum dot light-emitting layer 73b, an electron transport layer 74b, a cathode 75b and a first barrier layer 76b located between the hole transport layer 72b and the quantum dot light-emitting layer 73b.

For the above QLED device, the first barrier layer 76b located between the quantum dot light-emitting layer 73b and the hole transport layer 72b is composed of a plurality of chain polymer electrolytes, and has the net-shaped structure having a certain compact degrees, and the net-shaped structure can block the nanoparticles in the hole transport layer 72b and block the nanoparticles from penetrating into the quantum dot light-emitting layer 73b by gravity, thereby ensuring the light-emitting performance of the quantum dot light-emitting layer 73b. The polymer electrolyte may be materials such as amine-containing polyfluorenes conjugated polymers PFN, phenolic resins PF, renewable polyethylene terephthalate PETE, polyetherimide PEI, polyterephthalate plastics PET and polyethylene naphthalate PEN.

Based on the above scheme, as shown in FIG. 8, the QLED device of the disclosure mainly includes: a second transport layer 84 located below a quantum dot light-emitting layer 83; and a second barrier layer 87 located between the second transport layer 84 and the quantum dot light-emitting layer 83, the second barrier layer 87 containing the polymer electrolyte; wherein the second barrier layer 87 is configured to block particles in the quantum dot light-emitting layer 83 from leaking into the second transport layer 84.

The above QLED device can have the following two structures:

Structure a: the first transport layer is the electron transport layer, and the second transport layer is the hole transport layer.

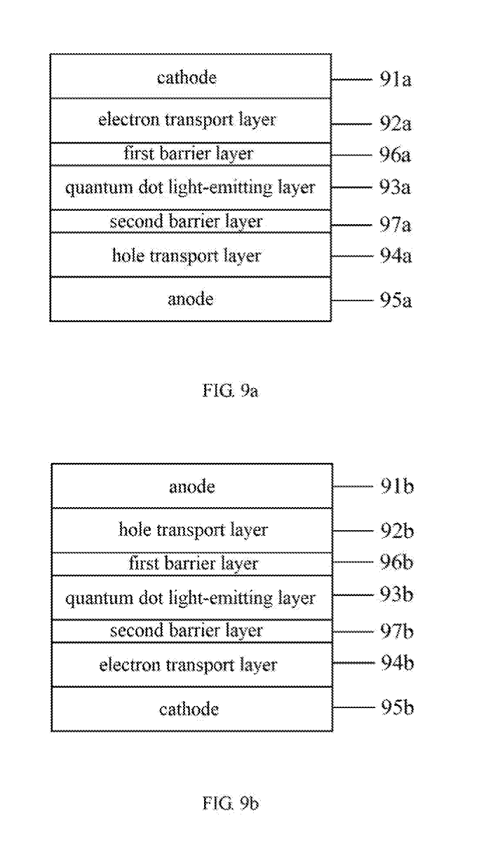

As shown in FIG. 9a, the QLED device includes a cathode 91a, an electron transport layer 92a, a quantum dot light-emitting layer 93a, a hole transport layer 94a, an anode 95a, a first barrier layer 96a disposed between the electron transport layer 92a and the quantum dot light-emitting layer 93a, and a second barrier layer 97a located between the hole transport layer 94a and the quantum dot light-emitting layer 93a.

For the above QLED structure, the polymer electrolyte has a net-shaped structure, i.e., the first barrier layer 96a located between the electron transport layer 92a and the quantum dot light-emitting layer 93a has the net-shaped structure, which can effectively separate the quantum dot light-emitting layer 93a from the electron transport layer 92a, avoiding the nanoparticles in the electron transport layer 92a from leaking into the quantum dot light-emitting layer 93a by gravity, and avoiding even mutual solubility between layers. Similarly, the second barrier layer 97a located between the hole transport layer 94a and the quantum dot light-emitting layer 93a has a dense net-shaped structure, avoiding the nanoparticles in the quantum dot light-emitting layer 93a from penetrating into the hole transport layer 94a and further ensuring the light-emitting performance of the quantum dot light-emitting layer 93a.

Structure b: the first transport layer is the hole transport layer, and the second transport layer is the electron transport layer.

As shown in FIG. 9b, the QLED device includes an anode 91b, a hole transport layer 92b, a quantum dot light-emitting layer 93b, an electron transport layer 94b, a cathode 95b, a first barrier layer 96b disposed between the hole transport layer 92b and the quantum dot light-emitting layer 93b, and a second barrier layer 97b located between the electron transport layer 94b and the quantum dot light-emitting layer 93b.

For the above QLED structure described above, the polymer electrolyte has the net-shaped structure, i.e., the first barrier layer 96b located between the hole transport layer 92b and the quantum dot light-emitting layer 93b has the net-shaped structure, which can effectively separate the quantum dot light-emitting layer 93b from the hole transport layer 92b, avoiding the nanoparticles in the hole transport layer 92b from leaking into the quantum dot light-emitting layer 93b by gravity and avoiding even mutual solubility between layers. Similarly, the second barrier layer 97b located between the electron transport layer 94b and the quantum dot light-emitting layer 93b can effectively separate the quantum dot light-emitting layer 93b and the electron transport layer 94b, avoiding the nanoparticles in the quantum dot light-emitting layer 93b from leaking into the electron transport layer 94b by gravity, and avoiding even mutual solubility between layers, thereby ensuring the light-emitting performance of the quantum dot light-emitting layer 93b.

Based on the device structure described above, the end group carried by the polymer electrolyte can fill the contact interface between the quantum dot light-emitting layer and the adjacent transport layer. Specifically, the nano-scaled particles are included in the quantum dot light-emitting layer, and surfaces of the particles have defects, and the nanoparticles contained in the transport layer may be inorganic nanoparticles having semiconductor properties, and the surfaces of the nanoparticles also have defects. When the QLED device is working, the above defects will capture electrons, hinder electron conduction and even the interface quenching phenomenon arises, affecting the light-emitting effect of the QLED device. In the present scheme, the polymer electrolyte is an electrolyte in the form of a polymer. When the QLED device is working, the polymer electrolyte tends to have a dipole, and fills the surface of the nanoparticles of the quantum dot light-emitting layer contacting with the electron transport layer or the hole transport layer, thereby improving defects at the contact interface between the quantum dot light-emitting layer and the transport layer, reducing the density of the defect state and optimizing the light-emitting performance of the QLED device.

### Exemplary Embodiment 4

The exemplary embodiment of the disclosure provides a QLED apparatus including any one of the QLED devices mentioned above. The QLED device can be any products or components with display function, such as a mobile phone, a tablet computer, a television, a display, a notebook computer, a digital photo frame, a navigator, a smart wearable device, a virtual reality device, an augmented reality device and the like, and can also be used for lighting devices. Other components indispensable to the display device should be understood by a person skilled in the art, which are not described in detail herein, nor should be construed as a limitation to the disclosure.

The above description is only the exemplary embodiments of the disclosure and is not intended to limit the disclosure. As for a person skilled in the art, there are various modifications and changes in the disclosure. Any equivalent modifications, equivalent substitutions, improvements and the like made within the spirit and principle of the disclosure should be included in the scope of the appended claims of the disclosure.

What is claimed is:

1. A quantum dot light-emitting diode device, comprising:
a quantum dot light-emitting layer,
a first transport layer located above the quantum dot light-emitting layer, and
a first barrier layer located between the quantum dot light-emitting layer and the first transport layer, the first barrier layer comprising a polymer electrolyte,
the first barrier layer blocking at least a portion of nanoparticles in the first transport layer from leaking to the quantum dot light-emitting layer.

2. The quantum dot light-emitting diode device according to claim 1, further comprising: a second transport layer located below the quantum dot light-emitting layer;
a second barrier layer located between the second transport layer and the quantum dot light-emitting layer, the second barrier layer comprising a polymer electrolyte.

3. The quantum dot light-emitting diode device according to claim 1, wherein the polymer electrolyte has a net-shaped structure.

4. The quantum dot light-emitting diode device according to claim 3, wherein the net-shaped structure is made of a chain polymer electrolyte.

5. The quantum dot light-emitting diode device according to claim 1, wherein the barrier layer has a thickness of 8 to 15 nm.

6. The quantum dot light-emitting diode device according to claim 1, wherein the polymer electrolyte comprises any one or more of amine-containing polyfluorenes conjugated polymers PFN, phenolic resins PF, renewable polyethylene terephthalate PETE, polyetherimide PEI, polyterephthalate plastics PET and polyethylene naphthalate.

7. A method of manufacturing a quantum dot light-emitting diode device, comprising:
forming a quantum dot light-emitting layer; forming a first barrier layer over the quantum dot light-emitting layer, the first barrier layer comprising a polymer electrolyte; forming a first transport layer over the first barrier layer;
the first barrier layer blocking at least a portion of nanoparticles in the first transport layer from leaking to the quantum dot light-emitting layer.

8. The method of manufacturing a quantum dot light-emitting diode device according to claim 7, wherein the forming a first barrier layer over the quantum dot light-emitting layer specifically comprises:
dissolving a polymer electrolyte with a first solvent to form a first solution having a preset concentration;
depositing the first solution over the quantum dot light-emitting layer to form the first barrier layer.

9. The method of manufacturing a quantum dot light-emitting diode device according to claim 8, wherein a second solvent used to dissolve the nanoparticles when forming the first transport layer is immiscible with the first solvent.

10. The method of manufacturing a quantum dot light-emitting diode device according to claim 9, wherein the first solvent is a polar solvent and the second solvent is a non-polar solvent.

11. The method of manufacturing a quantum dot light-emitting diode device according to claim 7, wherein before forming the quantum dot light-emitting layer, the method further comprises:
forming a second transport layer; forming a second barrier layer over the second transport layer, the second barrier layer comprising a polymer electrolyte.

12. The method of manufacturing a quantum dot light-emitting diode device according to claim 11, wherein the forming a second barrier layer over the second transport layer specifically comprises:
dissolving a polymer electrolyte with a third solvent to form a third solution having a preset concentration;
depositing the third solution on the second transport layer to form the second barrier layer.

13. The method of manufacturing a quantum dot light-emitting diode device according to claim 8, wherein the preset concentration is less than 1 mg/ml.

14. A quantum dot light-emitting diode apparatus, comprising a quantum dot light-emitting diode device, the quantum dot light-emitting diode device, comprising: a quantum dot light-emitting layer, a first transport layer located above the quantum dot light-emitting layer, and a first barrier layer located between the quantum dot light-emitting layer and the first transport layer, the first barrier layer comprising a polymer electrolyte;
the first barrier layer blocking at least a portion of nanoparticles in the first transport layer from leaking to the quantum dot light-emitting layer.
